(19) United States
(12) Patent Application Publication
(10) Pub. No.: US 2026/0334052 A1
(43) Pub. Date: Oct. 22, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-si (KR)

(72) Inventors: Intae Son, Yongin-si (KR); Dasong Lee, Yongin-si (KR); Junsu Park, Yongin-si (KR)

(21) Appl. No.: 19/391,380

(22) Filed: Nov. 17, 2025

(30) Foreign Application Priority Data
Mar. 28, 2025 (KR) 10-2025-0040161

(51) Int. Cl. H10K 59/80; H10K 59/12; H10K 102/00

(52) U.S. Cl. CPC H10K 59/8722; H10K 59/1201; H10K 59/879; H10K 59/8793; H10K 2102/351

(57) ABSTRACT

A display device, a method of manufacturing the display device, and an electronic device including the display device are disclosed. The display device may include a substrate including a hole area, a display area, and a non-display area around at least a portion of the display area, a circuit layer provided on the substrate and including a circuit element, an element layer provided on the circuit layer and including a light-emitting element, a polarizing plate provided on the element layer and including an opening in the hole area, a filling layer filling the opening of the polarizing plate, an adhesive layer on the polarizing plate and the filling layer, wherein the adhesive layer has a thickness of equal to or less than about 100 micrometers and a transmittance of equal to or less than about 90% with respect to ultraviolet rays, and a cover window on the adhesive layer.

### CROSS-REFERENCE TO RELATED APPLICATION

The present application claims priority to and the benefit of Korean Patent Application No. 10-2025-0040161, filed on Mar. 28, 2025, in the Korean Intellectual Property Office, the entire disclosure of which is incorporated herein by reference.

### BACKGROUND

### 1. Field

One or more embodiments of the present disclosure relate to a display device, a method of manufacturing the display device, and an electronic device including the display device. For example, one or more embodiments of the present disclosure relate to a display device that provides visual information, a method of manufacturing the display device, and an electronic device including the display device.

### 2. Description of the Related Art

Display devices are used to display images to provide visual information to users. Among display devices, organic light emitting display devices have attracted attention.

The display devices may include a display panel, a polarizing plate on the display panel, and a cover window on the polarizing plate. External light incident on the display device may be reflected from wiring, electrodes, and/or the like, and the polarizing plate may block reflection of such external light. The cover window may protect the display panel and the polarizing plate.

As an area occupied by the display area in the display device is expanded, one or more suitable functions may be added to the display area. For example, the display device may include an imaging element, a sensor, and/or the like in the display area.

### SUMMARY

One or more aspects of embodiments of the present disclosure are directed toward a display device having improved or enhanced quality (e.g., display quality).

One or more aspects of embodiments of the present disclosure are directed toward a method of manufacturing the display device.

One or more aspects of embodiments of the present disclosure are directed toward an electronic device including the display device.

Additional aspects of embodiments will be set forth in part in the description which follows and, in part, will be apparent from the description or may be learned by practice of the presented embodiments of the disclosure.

A display device according to one or more embodiments includes a substrate including a hole area, a display area, and a non-display area around (e.g., surrounding) at least a portion of the display area, a circuit layer located or provided on the substrate and including a circuit element, an element layer located or provided on the circuit layer and including a light-emitting element, a polarizing plate located or provided on the element layer and including an opening in the hole area, a filling layer filling the opening of the polarizing plate, an adhesive layer located or provided on the polarizing plate and the filling layer, and a cover window located or provided on the adhesive layer.

In one or more embodiments, the adhesive layer may have a thickness of equal to or less than about 100 micrometers and a transmittance of equal to or less than about 90 % with respect to ultraviolet (UV) rays.

In one or more embodiments, the transmittance of the adhesive layer with respect to ultraviolet rays may be equal to or more than about 85 %.

In one or more embodiments, a creep property of the filling layer may be equal to or more than about 80 % and equal to or less than about 90 %.

In one or more embodiments, an indentation modulus of the filling layer may be equal to or more than about 60 kPa and equal to or less than about 80 kPa.

In one or more embodiments, the display device may further include a component located or provided in the hole area.

In one or more embodiments, the element layer may define a hole overlapping the opening in plan view.

In one or more embodiments, the display device may further include a filling member filling the hole.

In one or more embodiments, the filling layer may be cured by ultraviolet rays transmitted through the adhesive layer.

In one or more embodiments, the filling layer and the adhesive layer may be cured concurrently (e.g., simultaneously).

In one or more embodiments, a refractive index of the adhesive layer may be equal to or more than about 1.49 and equal to or less than about 1.5.

A method of manufacturing a display device according to one or more embodiments includes forming or providing a preliminary polarizing plate on a display panel, forming or providing a polarizing plate by forming or providing an opening in the preliminary polarizing plate, forming or providing a filling layer filling the opening, forming or providing an adhesive layer on the polarizing plate and the filling layer, and forming or providing a cover window on the adhesive layer.

In one or more embodiments, the adhesive layer may have a thickness of equal to or less than about 100 micrometers and a transmittance of equal to or less than about 90 % with respect to ultraviolet rays.

In one or more embodiments, the method may further include partially curing the filling layer after the forming or providing of the filling layer and before the forming or providing of the adhesive layer.

In one or more embodiments, the method may further include fully (e.g., substantially fully) curing the filling layer after the forming or providing of the cover window.

In one or more embodiments, the adhesive layer may be cured by the fully (e.g., substantially fully) curing of the filling layer.

In one or more embodiments, a transmittance of the adhesive layer with respect to ultraviolet rays may be equal to or more than about 85 %.

In one or more embodiments, a creep property of the filling layer may be equal to or more than about 80 % and equal to or less than about 90 %, and an indentation modulus of the filling layer may be equal to or more than about 60 kPa and equal to or less than about 80 kPa.

An electronic device according to one or more embodiments includes a display device, wherein the display device includes a substrate including a hole area, a display area, and a non-display area around (e.g., surrounding) at least a portion of the display area, a circuit layer located or provided on the substrate and including a circuit element, an element layer located or provided on the circuit layer and including a light-emitting element, a polarizing plate located or provided on the element layer and including an opening in the hole area, a filling layer filling the opening of the polarizing plate, an adhesive layer located or provided on the polarizing plate and the filling layer, wherein the adhesive layer has a thickness of equal to or less than about 100 micrometers and a transmittance of equal to or less than about 90 % with respect to ultraviolet rays, and a cover window located or provided on the adhesive layer, and a memory configured or provided to store data information.

In one or more embodiments, the transmittance of the adhesive layer with respect to ultraviolet rays may be equal to or more than about 85 %.

In one or more embodiments, a creep property of the filling layer may be equal to or more than about 80 % and equal to or less than about 90 %, and an indentation modulus of the filling layer may be equal to or more than about 60 kPa and equal to or less than about 80 kPa.

In one or more embodiments, a refractive index of the adhesive layer may be equal to or more than about 1.49 and equal to or less than about 1.5.

A display device according to one or more embodiments may include a substrate including a hole area, a display area, and a non-display area around (e.g., surrounding) at least a portion of the display area, a circuit layer located or provided on the substrate and including a circuit element, an element layer located or provided on the circuit layer and including a light-emitting element, a polarizing plate located or provided on the element layer and including an opening in the hole area, a filling layer filling the opening of the polarizing plate, an adhesive layer located or provided on the polarizing plate and the filling layer, and a cover window located or provided on the adhesive layer. The adhesive layer may have a thickness of equal to or less than about 100 micrometers and a transmittance of equal to or less than about 90 % with respect to ultraviolet rays.

Accordingly, a crosslinking reaction may sufficiently or suitably occur in an entire (e.g., substantially entire) area of the filling layer, and the filling layer may have a high crosslinking density. Accordingly, an elastic modulus of the filling layer may increase, and a creep property may decrease. Accordingly, a degree to which the filling layer expands or contracts according to external temperature change may decrease. Accordingly, cracks, delamination, and/or the like that occur in a portion of the polarizing plate may be prevented (or a degree to or occurrence of which cracks, delamination, and/or the like occur in a portion of the polarizing plate and/or the like may be reduced). Accordingly, bubbles that occur in the cracks, delamination, and/or the like may be prevented (or a degree to or occurrence of which bubbles occur in the cracks, delamination, and/or the like may be reduced).

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a plan view illustrating a display device according to one or more embodiments.

FIG. 2 is a cross-sectional view illustrating the display device of FIG. 1.

FIG. 3 is a cross-sectional view taken along the line I-I` of the display device of FIG. 1.

FIG. 4 is a cross-sectional view illustrating one or more components included in the display device of FIG. 3.

FIG. 5 is a cross-sectional view illustrating a pixel included in the display device of FIG. 1.

FIGS. 6-10 are cross-sectional views illustrating a method of manufacturing the display device of FIG. 1.

FIG. 11 is a block diagram illustrating an electronic device according to one or more embodiments.

FIG. 12 is a schematic diagram of electronic devices according to one or more embodiments.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the specification.

The utilization of “may” if (e.g., when) describing embodiments of the present disclosure refers to “one or more embodiments of the present disclosure.”

In the context of the present application and unless otherwise defined, the terms "use," "using," and "used" may be considered synonymous with the terms "utilize," "utilizing," and "utilized," respectively.

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, "at least one of a, b, or c," “at least one selected from among a, b, and c,” "at least one selected from among a to c," and/or the like indicates only a, only b, only c, both (e.g., simultaneously) a and b, both (e.g., simultaneously) a and c, both (e.g., simultaneously) b and c, all of a, b, and c, or variations thereof.

As used herein, “combination thereof” may refer to a mixture, a stack, a composite, a copolymer, an alloy, a blend, a reaction product, and/or the like of constituents.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30 %, ±20 %, ±10 %, or ±5 % of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

It will be understood that if (e.g., when) an element, such as a layer, a film, a region, or a substrate, is referred to as being “on” or “above” another element, it may be directly on the other element or intervening elements may also be present therebetween. In contrast, if (e.g., when) an element is referred to as being “directly on” or “directly above” another element, there are no intervening elements present therebetween.

In the drawings, the thickness of layers, films, panels, regions, and/or the like may be exaggerated for clarity. In the drawings, the thickness of a part of layers, regions, and/or the like may be exaggerated for better understanding and ease of description.

The shapes, sizes, ratios, angles, numbers, and/or the like disclosed in the drawings to illustrate one or more embodiments of the present disclosure are examples, and therefore embodiments of the present disclosure are not limited to the disclosed embodiments.

It will be understood that, although the terms “first,” “second,” “third,” and/or the like may be used herein to describe one or more elements, components, regions, layers, and/or sections, these elements, components, regions, layers, and/or sections should not be limited by these terms. These terms are used to distinguish one element, component, region, layer, or section from another element, component, region, layer, or section. Thus, a first element, a first component, a first region, a first layer, or a first section as described herein may be termed a second element, a second component, a second region, a second layer, or a second section, without departing from the spirit and scope of the present disclosure.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

Hereinafter, display devices in accordance with one or more embodiments of the present disclosure will be described in more detail with reference to the accompanying drawings.

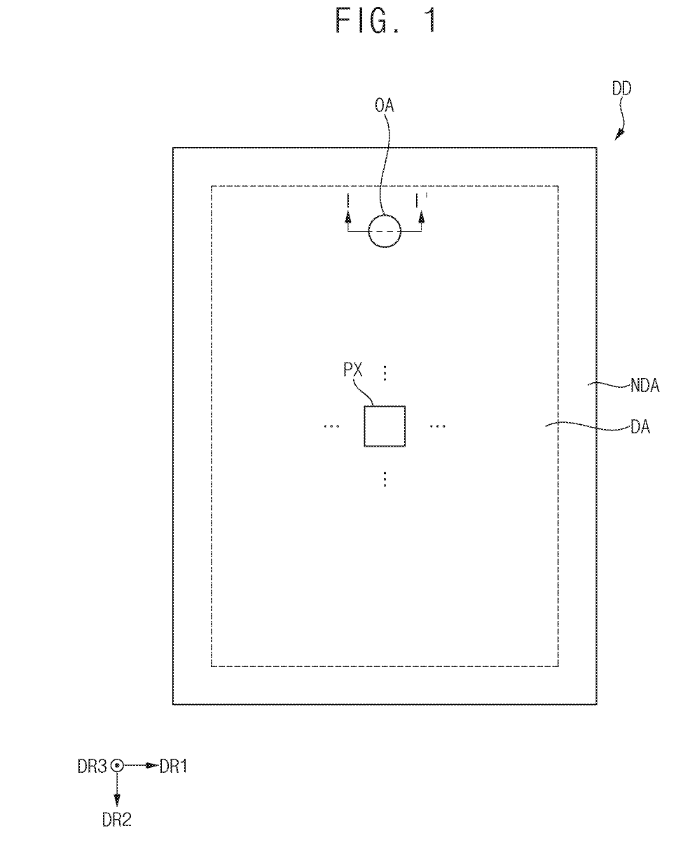

FIG. 1 is a plan view illustrating a display device according to one or more embodiments.

Referring to FIG. 1, a display device DD according to one or more embodiments may include a display area DA, a non-display area NDA, and a hole area OA.

The display area DA may be an area in which an image is displayed. For example, the display area DA may be defined as an area capable of displaying an image by generating light or adjusting transmittance of light provided from an external light source. Pixels PX may be located or provided in the display area DA. Each of the pixels PX may emit light. The pixels PX may be repeatedly arranged along a first direction DR1 and a second direction DR2 crossing the first direction DR1. As each of the pixels PX emits light in the display area DA, the display area DA may display an image.

The non-display area NDA may be around (e.g., surround) at least a portion of the display area DA. For example, the non-display area NDA may entirely (e.g., substantially entirely) be around (e.g., surround) the display area DA. A plurality of drivers may be located or provided in the non-display area NDA. For example, the plurality of drivers may include a scan driver, a data driver, a light-emitting control driver, and/or the like. In one or more embodiments, the non-display area NDA may not emit light. For example, the pixels PX may not be located or provided in the non-display area NDA. However, embodiments of the present disclosure are not necessarily limited thereto, and a portion of the non-display area NDA may emit light.

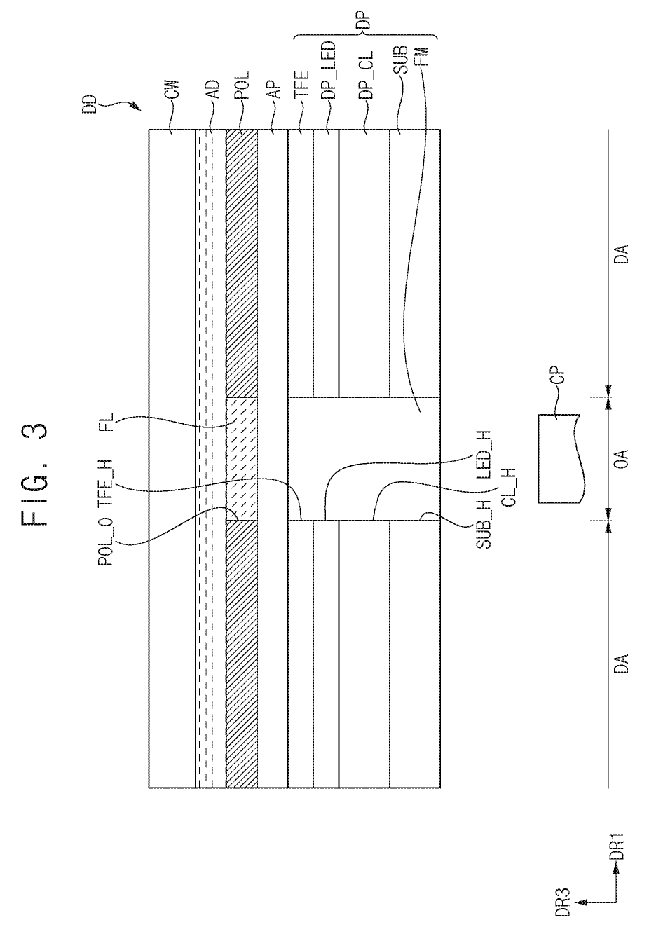

In one or more embodiments, the hole area OA may be located or provided in the display area DA. For example, the hole area OA may be located or provided at an upper center of the display area DA. However, embodiments of the present disclosure are not necessarily limited thereto, and in one or more embodiments, the hole area OA may be located or provided at an upper left or an upper right of the display area DA. In one or more embodiments, the hole area OA may be located or provided in the non-display area NDA. A component (e.g., a component CP of FIG. 3), which will be described herein in more detail, may be located or provided in the hole area OA.

In one or more embodiments, the first direction DR1 and the second direction DR2 crossing the first direction DR1 may be defined. For example, the second direction DR2 may be substantially perpendicular to the first direction DR1. However, embodiments of the present disclosure are not necessarily limited thereto, and the second direction DR2 may form an acute angle or an obtuse angle with the first direction DR1. In one or more embodiments, a third direction DR3 crossing a plane formed by the first direction DR1 and the second direction DR2 may be defined. For example, the third direction DR3 may be substantially perpendicular to the plane formed by the first direction DR1 and the second directions DR2. However, embodiments of the present disclosure are not necessarily limited thereto, and the third direction DR3 may form an acute angle or an obtuse angle with the plane formed by the first direction DR1 and the second direction DR2.

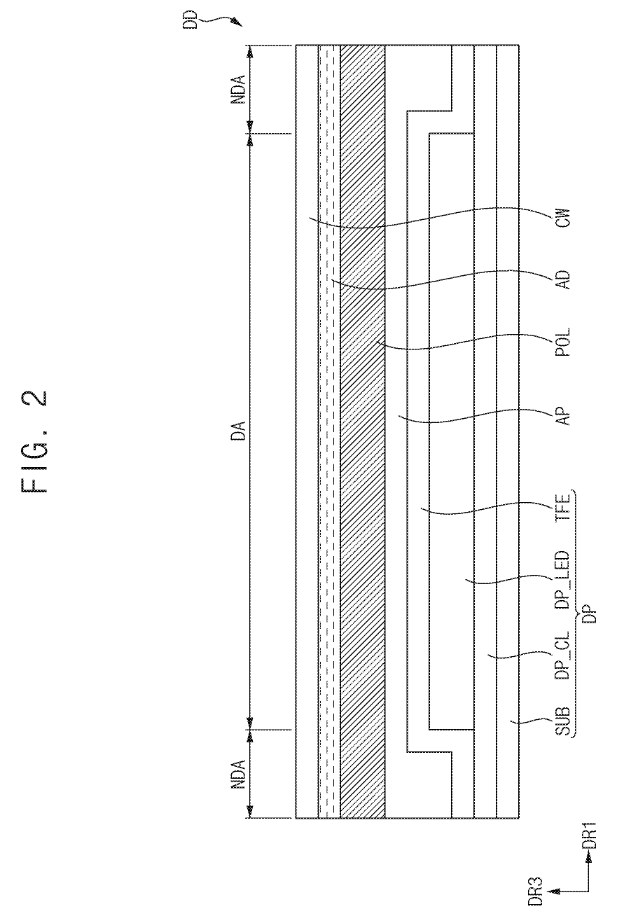

FIG. 2 is a cross-sectional view illustrating the display device of FIG. 1.

Referring to FIG. 2, the display device DD according to one or more embodiments may include a display panel DP, a panel adhesive layer AP, a polarizing plate POL, an adhesive layer AD, and a cover window CW.

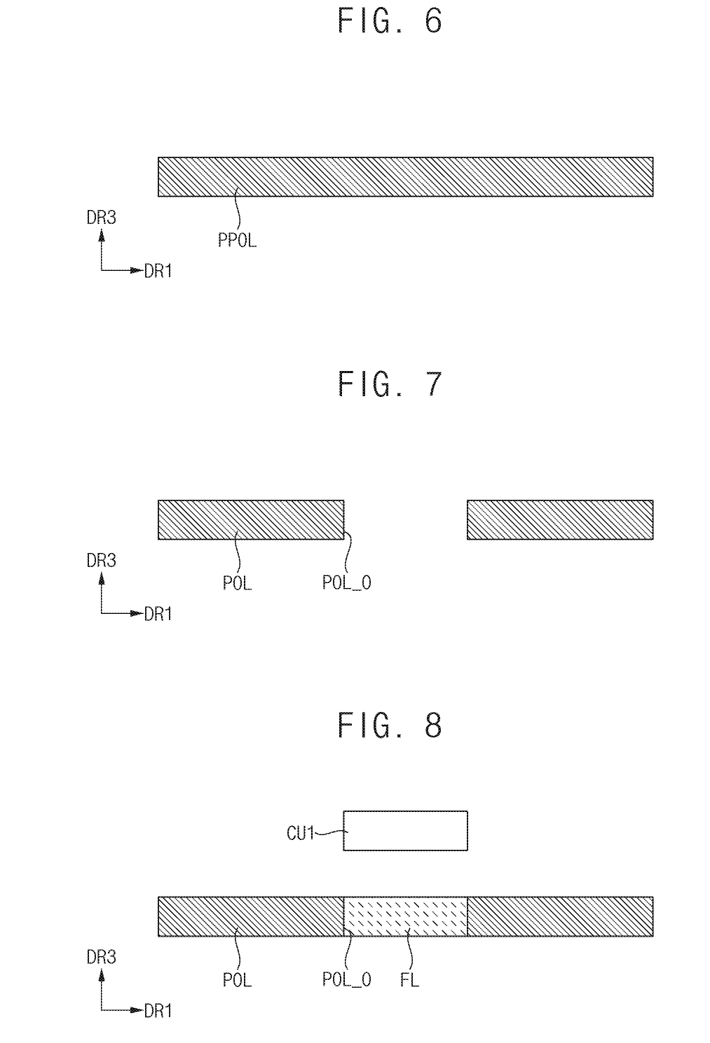

The display panel DP may display an image according to an electrical signal. For example, the display panel DP may include the pixels (e.g., the pixels PX of FIG. 1). The display panel DP may include a substrate SUB, a circuit layer DP_CL, an element layer DP_LED, and an encapsulation layer TFE. The substrate SUB may be a base layer of the display panel DP. The circuit layer DP_CL may be located or provided on the substrate SUB. The circuit layer DP_CL may include a circuit element. For example, the circuit layer DP_CL may include a transistor (e.g., a transistor TR of FIG. 5) and a capacitor. The element layer DP_LED may be located or provided on the circuit layer DP_CL. The element layer DP_LED may include a light-emitting element (e.g., a light-emitting element LED of FIG. 5). The element layer DP_LED may be located or provided in the display area DA. The encapsulation layer TFE may be located or provided on the element layer DP_LED. The encapsulation layer TFE may seal the element layer DP_LED.

The polarizing plate POL may be located or provided on the display panel DP. The polarizing plate POL may block reflection of external light incident on the display device DD. For example, the external light incident on the display device DD may be reflected from wiring, electrodes, and/or the like, and the polarizing plate POL may block such reflection of the external light. For example, the polarizing plate POL may include a phase retardation film, such as a linear polarizer, a λ/4 plate, and/or the like, but embodiments of the present disclosure are not necessarily limited thereto.

The polarizing plate POL may be attached to the display panel DP through the panel adhesive layer AP. The panel adhesive layer AP may include an optical clear adhesive (OCA), an optical clear resin (OCR), or a pressure sensitive adhesive (PSA).

The cover window CW may be located or provided on the polarizing plate POL. The cover window CW may protect components included in the display device DD from external impact. For example, the cover window CW may include ultra thin glass or a polyimide film, but embodiments of the present disclosure are not necessarily limited thereto.

The cover window CW may be attached to the polarizing plate POL through the adhesive layer AD. The adhesive layer AD may include an optical clear adhesive (OCA), an optical clear resin (OCR), or a pressure sensitive adhesive (PSA).

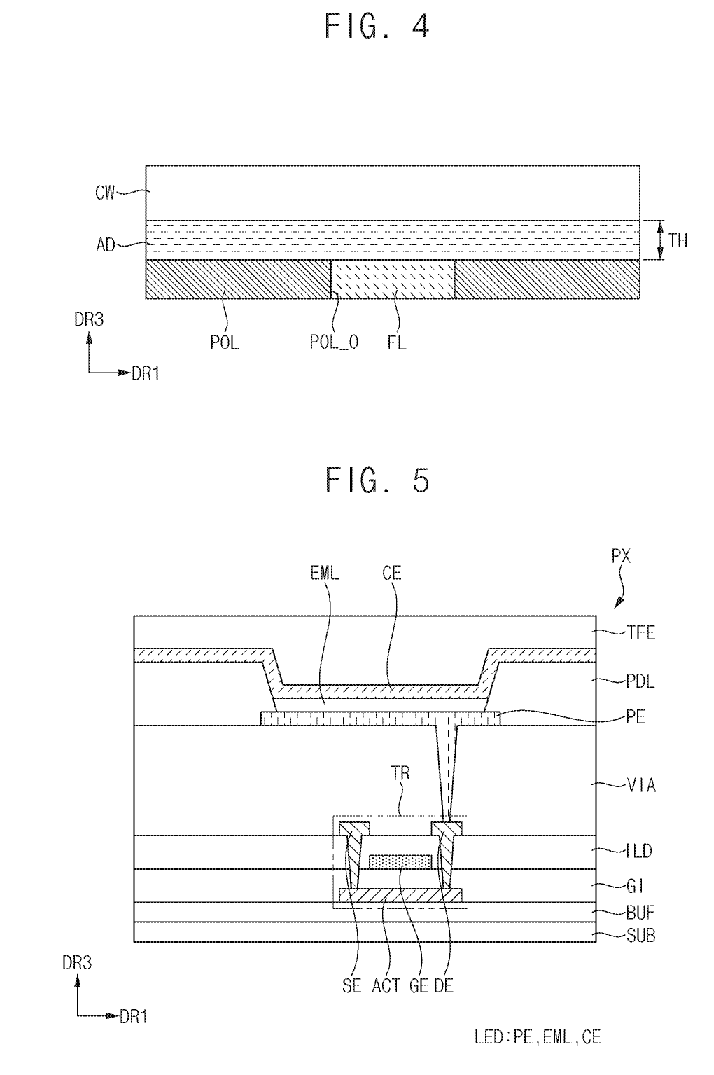

FIG. 3 is a cross-sectional view taken along the line I-I` of the display device of FIG. 1. FIG. 4 is a cross-sectional view illustrating one or more components included in the display device of FIG. 3.

For example, FIG. 4 is a cross-sectional view illustrating the polarizing plate POL, a filling layer FL, the adhesive layer AD, and the cover window CW.

Referring to FIG. 3, as described in one or more embodiments, the display device DD may include the display panel DP, the panel adhesive layer AP, the polarizing plate POL, the adhesive layer AD, and the cover window CW. In one or more embodiments, the display device DD may further include a component CP, a filling member FM, and a filling layer FL. The filling member FM may be a component included in the display panel DP. For example, the display panel DP may include the substrate SUB, the circuit layer DP_CL, the element layer DP_LED, the encapsulation layer TFE, and the filling member FM.

The substrate SUB may include a first hole SUB_H. The first hole SUB_H may be a portion removed from an upper surface to a lower surface of the substrate SUB. The first hole SUB_H may be located or provided in the hole area OA.

The circuit layer DP_CL may include a second hole CL_H. The second hole CL_H may be a portion removed from an upper surface to a lower surface of the circuit layer DP_CL. The second hole CL_H may be located or provided in the hole area OA. The second hole CL_H may overlap the first hole SUB_H in plan view.

The element layer DP_LED may include a third hole LED_H. The third hole LED_H may be a portion removed from an upper surface to a lower surface of the element layer DP_LED. The third hole LED_H may be located or provided in the hole area OA. The third hole LED_H may overlap the first hole SUB_H and the second hole CL_H in plan view.

The encapsulation layer TFE may include a fourth hole TFE_H. The fourth hole TFE_H may be a portion removed from an upper surface to a lower surface of the encapsulation layer TFE. The fourth hole TFE_H may be located or provided in the hole area OA. The fourth hole TFE_H may overlap the first hole SUB_H, the second hole CL_H, and the third hole LED_H in plan view.

The filling member FM may be located or provided in the hole area OA. The filling member FM may fill the first hole SUB_H, the second hole CL_H, the third hole LED_H, and the fourth hole TFE_H. For example, the first hole SUB_H, the second hole CL_H, the third hole LED_H, and the fourth hole TFE_H may be spatially connected to form or provide a through-hole, and the filling member FM may fill the through-hole. In one or more embodiments, the filling member FM may include an organic material that transmit light. For example, the filling member FM may include a phenol resin, an acrylic resin, a polyimide resin, a polyamide resin, a siloxane resin, an epoxy resin, and/or the like. These materials may be used alone or in combination with each other.

The component CP may be located or provided in the hole area OA. The component CP may overlap the first hole SUB_H, the second hole CL_H, the third hole LED_H, and the fourth hole TFE_H in plan view. In one or more embodiments, the component CP may include an electronic element using light. For example, the component CP may include an electronic element using infrared rays or visible light. For example, the component CP may include a solar cell, a flash, an illuminance sensor, a proximity sensor, an iris sensor, and/or the like. In one or more embodiments, the component CP may include an electronic element using sound. For example, the component CP may include a sensor, a speaker, and/or the like to detect or output sound. Light, sound, and/or the like output from the component CP to an outside of the display device DD may transmit through the filling member FM. In one or more embodiments, light, sound, and/or the like traveling from the outside of the display device DD toward the component CP may transmit through the filling member FM. In one or more embodiments, the component CP may be located or provided under the substrate SUB, but embodiments of the present disclosure are not necessarily limited thereto, and a location of the component CP may be suitably changed within the hole area OA.

The polarizing plate POL may include an opening POL_O. The opening POL_O may be a portion removed from an upper surface to a lower surface of the polarizing plate POL. The opening POL_O may be located or provided in the hole area OA. The opening POL_O may overlap the first hole SUB_H, the second hole CL_H, the third hole LED_H, and the fourth hole TFE_H in plan view.

The filling layer FL may fill the opening POL_O. The filling layer FL may be located or provided in the hole area OA. The adhesive layer AD may be located or provided on the polarizing plate POL and the filling layer FL. For example, the adhesive layer AD may contact the polarizing plate POL and the filling layer FL. The filling layer FL may include a photocurable resin, a photoinitiator, and/or the like. The photocurable resin may include a material cured by ultraviolet rays, but embodiments of the present disclosure are not necessarily limited thereto. The photoinitiator may be activated by ultraviolet rays to generate free radicals or ions, but embodiments of the present disclosure are not necessarily limited thereto.

Referring further to FIG. 4, as a weight of the display device DD is reduced and a thickness of the display device DD (e.g., a thickness in the third direction DR3) decreases, a thickness in the third direction DR3 of components included in the display device DD may also decrease. For example, as the thickness in the third direction DR3 of the display device DD decreases, a thickness TH in the third direction DR3 of the adhesive layer AD may decrease. For example, the thickness TH in the third direction DR3 of the adhesive layer AD may be equal to or less than about 100 micrometers. For example, the thickness TH in the third direction DR3 of the adhesive layer AD may be equal to or more than about 70 micrometers and equal to or less than about 100 micrometers, but embodiments of the present disclosure are not necessarily limited thereto.

FIG. 5 is a cross-sectional view illustrating a pixel included in the display device of FIG. 1.

Referring to FIG. 5, the pixel PX may include a substrate SUB, a buffer layer BUF, a gate insulating layer GI, an interlayer insulating layer ILD, a via insulating layer VIA, a transistor TR, a light-emitting element LED, a pixel defining layer PDL, and an encapsulating layer TFE.

The transistor TR may include an active layer ACT, a source electrode SE, a gate electrode GE, and a drain electrode DE. The light-emitting element LED may include a pixel electrode PE, a light-emitting layer EML, and a common electrode CE.

The substrate SUB may include a transparent (e.g., substantially transparent) material or an opaque material. The substrate SUB may be formed or composed of a transparent (e.g., substantially transparent) resin substrate. Example of the transparent resin substrate may include a polyimide substrate. In this case, the polyimide substrate may include a first organic layer, a first barrier layer, a second organic layer, and/or the like. In one or more embodiments, the substrate SUB may include a quartz substrate (e.g., a synthetic quartz substrate, a fluorine-doped quartz substrate, and/or the like), a calcium fluoride substrate, a sodalime glass substrate, a non-alkali glass substrate, and/or the like. These materials may be used alone or in combination with each other.

The buffer layer BUF may be located or provided on the substrate SUB. The buffer layer BUF may prevent metal atoms and/or impurities from diffusing from the substrate SUB to the transistor TR (or reduce a degree to or occurrence of which metal atoms and/or impurities diffuse from the substrate SUB to the transistor TR). In one or more embodiments, the buffer layer BUF may improve or enhance flatness of a surface of the substrate SUB if (e.g., when) the surface of the substrate SUB is not uniform. For example, the buffer layer BUF may include inorganic materials, such as silicon oxide (e.g., SiOₓ,wherein 0 < x ≤ 2; e.g., SiO₂), silicon nitride (e.g., SiNₓ, wherein 0 < x ≤ 2; e.g., Si₃N₄), silicon carbide (e.g., SiCₓ,wherein 0 < x ≤ 2; e.g., SiC), silicon oxynitride (e.g., SiOₓN_{y}, wherein 0 < x ≤ 2 and 0 ≤ y ≤ 2; e.g., SiON or Si₂N₂O), silicon oxycarbide (e.g., SiOₓC_{y}, wherein 0 < x ≤ 2 and 0 ≤ y ≤ 2; e.g., SiOC), and/or the like. These materials may be used alone or in combination with each other.

The active layer ACT may be located or provided on the buffer layer BUF. The active layer ACT may include an inorganic semiconductor (e.g., amorphous (e.g., non-crystalline) silicon semiconductor, polysilicon semiconductor, a metal oxide semiconductor, and/or the like), an organic semiconductor, and/or the like. These materials may be used alone or in combination with each other. The active layer ACT may include a source area, a drain area, and a channel area located or provided between the source area and the drain area. The metal oxide semiconductor may include a binary compound (ABₓ), a ternary compound (ABₓC_{y}), a quaternary compound (ABₓC_{y}D_{z}), and/or the like including indium (In), zinc (Zn), gallium (Ga), tin (Sn), titanium (Ti), aluminum (Al), hafnium (Hf), zirconium (Zr), magnesium (Mg), and/or the like. These materials may be used alone or in combination with each other. For example, the metal oxide semiconductor may include zinc oxide (e.g., ZnOₓ, wherein 0 < x ≤ 2; e.g., ZnO), gallium oxide (e.g., GaOₓ, wherein 0 < x ≤ 2; e.g., Ga₂O₃), tin oxide (e.g., SnOₓ, wherein 0 < x ≤ 2; e.g., SnO₂), indium oxide (e.g., InOₓ, wherein 0 < x ≤ 2; In₂O₃), indium gallium oxide (IGO), indium zinc oxide (IZO), indium tin oxide (ITO), indium zinc tin oxide (IZTO), and indium gallium zinc oxide (IGZO). These materials may be used alone or in combination with each other.

The gate insulating layer GI may be located or provided on the buffer layer BUF. The gate insulating layer GI may sufficiently or suitably cover the active layer ACT. For example, the gate insulating layer GI may include inorganic materials, such as silicon oxide (e.g., SiOₓ,wherein 0 < x ≤ 2; e.g., SiO₂), silicon nitride (e.g., SiNₓ, wherein 0 < x ≤ 2; e.g., Si₃N₄), silicon carbide (e.g., SiCₓ,wherein 0 < x ≤ 2; e.g., SiC), silicon oxynitride e.g., SiOₓN_{y}, wherein 0 < x ≤ 2 and 0 ≤ y ≤ 2; e.g., SiON or Si₂N₂O), silicon oxycarbide (e.g., SiOₓC_{y}, wherein 0 < x ≤ 2 and 0 ≤ y ≤ 2; e.g., SiOC), and/or the like. These materials may be used alone or in combination with each other.

The gate electrode GE may be located or provided on the gate insulating layer GI. The gate electrode GE may overlap the channel area of the active layer ACT in plan view. The gate electrode GE may include a metal, an alloy, a metal nitride, a conductive (e.g., electrically conductive) metal oxide, a transparent (e.g., substantially transparent) conductive (e.g., electrically conductive) material, and/or the like. Examples of the metal may include silver (Ag), molybdenum (Mo), aluminum (Al), tungsten (W), copper (Cu”, nickel (Ni), chromium (Cr), titanium (Ti), tantalum (Ta), platinum (Pt), scandium (Sc), and/or the like. These materials may be used alone or in combination with each other. Examples of the conductive metal oxide may include indium tin oxide, indium zinc oxide, and/or the like. These materials may be used alone or in combination with each other. In one or more embodiments, examples of the metal nitride may include aluminum nitride (e.g., AlNₓ, wherein 0 < x ≤ 2; e.g., AlN), tungsten nitride (e.g., WNₓ, wherein 0 < x ≤ 2; e.g., W₂N, WN, and WN₂), chromium nitride (e.g., CrNₓ, wherein 0 < x ≤ 2; e.g., CrN), and/or the like. These materials may be used alone or in combination with each other.

The interlayer insulating layer ILD may be located or provided on the gate insulating layer GI. The interlayer insulating layer ILD may sufficiently or suitably cover the gate electrode GE. For example, the interlayer insulating layer ILD may include inorganic materials, such as silicon oxide (e.g., SiOₓ,wherein 0 < x ≤ 2; e.g., SiO₂), silicon nitride (e.g., SiNₓ, wherein 0 < x ≤ 2; e.g., Si₃N₄), silicon carbide (e.g., SiCₓ,wherein 0 < x ≤ 2; e.g., SiC), silicon oxynitride (e.g., SiOₓN_{y}, wherein 0 < x ≤ 2 and 0 ≤ y ≤ 2; e.g., SiON or Si₂N₂O), silicon oxycarbide (e.g., SiOₓC_{y}, wherein 0 < x ≤ 2 and 0 ≤ y ≤ 2; e.g., SiOC), and/or the like. These materials may be used alone or in combination with each other.

The source electrode SE may be located or provided on the interlayer insulating layer ILD. The source electrode SE may be connected to the source area of the active layer ACT through a contact hole penetrating (or, defined through) the gate insulating layer GI and the interlayer insulating layer ILD.

The drain electrode DE may be located or provided on the interlayer insulating layer ILD. The drain electrode DE may be connected to the drain area of the active layer ACT through a contact hole penetrating (or, defined through) the gate insulating layer GI and the interlayer insulating layer ILD.

For example, the source electrode SE may include a metal, an alloy, a metal nitride, a conductive (e.g., electrically conductive) metal oxide, a transparent (e.g., substantially transparent) conductive (e.g., electrically conductive) material, and/or the like. These materials may be used alone or in combination with each other. The drain electrode DE and the source electrode SE may be formed or provided through substantially the same process and may include substantially the same material.

The via insulating layer VIA may be located or provided on the interlayer insulating layer ILD. The via insulating layer VIA may sufficiently or suitably cover the source electrode SE and the drain electrode DE. The via insulating layer VIA may include an organic material. For example, the via insulating layer VIA may include organic materials, such as a phenolic resin, an acrylic resin, a polyimide resin, a polyamide resin, a siloxane resin, an epoxy resin, and/or the like. These materials may be used alone or in combination with each other.

The pixel electrode PE may be located or provided on the via insulating layer VIA. The pixel electrode PE may be connected to the drain electrode DE through a contact hole penetrating (or, define through) the via insulating layer VIA. The pixel electrode PE may include a metal, an alloy, a metal nitride, a conductive (e.g., electrically conductive) metal oxide, a transparent (e.g., substantially transparent) conductive (e.g., electrically conductive) material, and/or the like. These materials may be used alone or in combination with each other. In one or more embodiments, the pixel electrode PE may have a stacked structure including ITO/Ag/ITO. For example, the pixel electrode PE may operate as an anode of the light-emitting element LED.

The pixel defining layer PDL may be located or provided on the via insulating layer VIA. The pixel defining layer PDL may cover side portions of the pixel electrode PE. In one or more embodiments, an opening exposing a portion of the upper surface of the pixel electrode PE may be defined in the pixel defining layer PDL. For example, the pixel defining layer PDL may include an inorganic material and/or an organic material. In one or more embodiments, the pixel defining layer PDL may include an organic material, such as an epoxy resin, a siloxane resin, and/or the like. These materials may be used alone or in combination with each other. In one or more embodiments, the pixel defining layer PDL may further include a light blocking material containing a black pigment, a black dye, and/or the like.

The light emitting layer EML may be located or provided on the pixel electrode PE. The light emitting layer EML may include an organic material that emits light of a selected color. For example, the light emitting layer EML may include an organic material that emits red light. However, embodiments of the present disclosure are not necessarily limited thereto, and the light emitting layer EML may emit light of a different color from red light.

The common electrode CE may be located or provided on the light emitting layer EML and the pixel defining layer PDL. The common electrode CE may include a metal, an alloy, a metal nitride, a conductive (e.g., electrically conductive) metal oxide, a transparent (e.g., substantially transparent) conductive (e.g., electrically conductive) material, and/or the like. These materials may be used alone or in combination with each other. The common electrode CE may operate as a cathode of the light-emitting element LED.

The encapsulation layer TFE may be located or provided on the common electrode CE. The encapsulation layer TFE may prevent impurities, moisture, and/or the like from penetrating (or reduce a degree to or occurrence of which impurities, moisture, and/or the like penetrate) to the light-emitting element LED from an outside of the display device (e.g., the display device DD of FIG. 1). The encapsulation layer TFE may include at least one inorganic layer and at least one organic layer. For example, the inorganic layer may include silicon oxide, silicon nitride, silicon oxynitride, and/or the like. These materials may be used alone or in combination with each other. The organic layer may include a polymer cured material, such as polyacrylate.

One or more embodiments of the pixel PX have been described in more detail with reference to FIG. 5, but the pixel PX is not limited to a structure as illustrated in FIG. 5. For example, the pixel PX may include all structures that receive an electrical signal and emit light having a luminance corresponding to the intensity of the electrical signal.

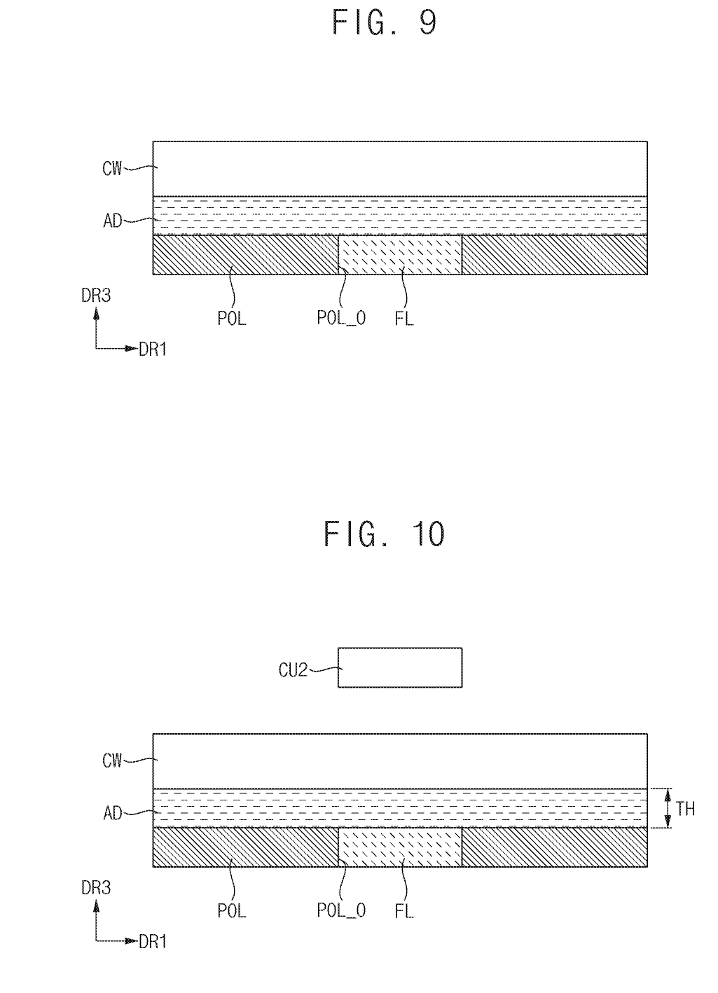

FIGS. 6, 7, 8, 9, and 10 are cross-sectional views illustrating a method of manufacturing the display device of FIG. 1.

For example, FIGS. 6, 7, 8, 9, and 10 are cross-sectional views illustrating a method of manufacturing the polarizing plate POL, the filling layer FL, the adhesive layer AD, and the cover window CW of FIG. 4.

Referring to FIG. 6, a preliminary polarizing plate PPOL may be formed or provided on the display panel (e.g., the display panel DP of FIG. 3). For example, the preliminary polarizing plate PPOL may be formed or provided to be attached to the display panel through the panel adhesive layer (e.g., the panel adhesive layer AP of FIG. 3).

Referring further to FIG. 7, an opening POL_O may be formed or provided in the preliminary polarizing plate PPOL. For example, the opening POL_O may be formed or provided in the hole area (e.g., the hole area OA of FIG. 3). Accordingly, the polarizing plate POL may be formed or provided. In one or more embodiments, the opening POL_O may be formed or provided through a laser cutting process. However, embodiments of the present disclosure are not necessarily limited thereto, and the opening POL_O may also be formed or provided by one or more suitable processes.

Referring to FIG. 8, the filling layer FL may be formed or provided to fill the opening POL_O. After the filling layer FL is formed or provided to fill the opening POL_O, the filling layer FL may be cured by a first curing unit CU1. The first curing unit CU1 may include a light-emitting member that emits light. For example, the first curing unit CU1 may include a UV-emitting LED module, a metal halide module, and/or the like, but embodiments of the present disclosure are not necessarily limited thereto, and the first curing unit CU1 may include any suitable light-emitting member that emits ultraviolet rays. The first curing unit CU1 may emit light having a wavelength of equal to or more than about 100 nanometers and equal to or less than about 400 nanometers, but embodiments of the present disclosure are not necessarily limited thereto, and a wavelength of light emitted by the first curing unit CU1 may be suitably changed depending on a type or kind of photoinitiator included in the filling layer FL. The filling layer FL may be cured by ultraviolet rays emitted from the first curing unit CU1. In one or more embodiments, the first curing unit CU1 may partially cure the filling layer FL without fully (e.g., substantially fully) curing the filling layer FL. For example, the first curing unit CU1 may partially cure the filling layer FL by emitting light of an irradiation dose smaller than an irradiation dose required or desired to fully (e.g., substantially fully) cure the filling layer FL.

Referring to FIG. 9, the adhesive layer AD may be formed or provided on the polarizing plate POL and the filling layer FL. For example, the adhesive layer AD may be attached to the polarizing plate POL and the filling layer FL through a lamination process, but embodiments of the present disclosure are not necessarily limited thereto.

The cover window CW may be formed or provided on the adhesive layer AD. For example, the cover window CW may be attached to the adhesive layer AD through a lamination process, but embodiments of the present disclosure are not necessarily limited thereto.

Referring to FIG. 10, the filling layer FL may be cured by a second curing unit CU2. The second curing unit CU2 may include a light-emitting member that emits light. For example, the second curing unit CU2 may include a UV-emitting LED module, a metal halide module, and/or the like, but embodiments of the present disclosure are not necessarily limited thereto, and the second curing unit CU2 may include any suitable light-emitting member that emits ultraviolet rays. The second curing unit CU2 may emit light having a wavelength of equal to or more than about 100 nanometers and equal to or less than about 400 nanometers, but embodiments of the present disclosure are not necessarily limited thereto, and a wavelength of light emitted by the second curing unit CU2 may be suitably changed depending on a type or kind of photoinitiator included in the filling layer FL. In one or more embodiments, the second curing unit CU2 may fully (e.g., substantially fully) cure the filling layer FL. For example, the second curing unit CU2 may perform full (e.g., substantially full) curing of the filling layer FL. In one or more embodiments, the second curing unit CU2 may cure the adhesive layer AD. For example, the adhesive layer AD and the filling layer FL may be cured concurrently (e.g., simultaneously) by the second curing unit CU2. For example, ultraviolet rays emitted from the second curing unit CU2 may transmit through the adhesive layer AD and reach the filling layer FL, and accordingly, the filling layer FL may be cured.

In one or more embodiments, a transmittance of the adhesive layer AD with respect to ultraviolet rays may be equal to or less than about 90 %. For example, the transmittance of the adhesive layer AD with respect to ultraviolet rays may be equal to or more than about 85 % and equal to or less than about 90 %.

If (e.g., when) the transmittance of the adhesive layer AD with respect to ultraviolet rays is lower than about 85 %, the filling layer FL may not be sufficiently or suitably cured. For example, if (e.g., when) the transmittance of the adhesive layer AD with respect to ultraviolet rays is lower than about 85 %, light of an irradiation dose smaller than an irradiation dose required or desired to fully (e.g., substantially fully) cure the filling layer FL may transmit through the adhesive layer AD from the second curing unit CU2. Accordingly, the filling layer FL may not be sufficiently or suitably cured. For example, if (e.g., when) the transmittance of the adhesive layer AD with respect to ultraviolet rays is lower than about 85 %, it may not be easy to fully (e.g., substantially fully) cure the filling layer FL.

A photoinitiator included in the filling layer FL may be activated by ultraviolet rays emitted from the second curing unit CU2 and transmitted through the adhesive layer AD. If (e.g., when) the transmittance of the adhesive layer AD with respect to ultraviolet rays is higher than about 90 %, the photoinitiator may be activated only in a partial area of the filling layer FL by the second curing unit CU2. Accordingly, a crosslinking reaction may occur only in a partial area of the filling layer FL. As a result, a crosslinking density of the filling layer FL may be lowered, and the filling layer FL may include a loose crosslink network. Therefore, an elastic modulus of the filling layer FL may decrease, and a creep rate may increase. Accordingly, the filling layer FL may more sensitively respond to external temperature change and may expand or contract more easily. As a result, cracks, delamination, and/or the like may occur at a portion where the filling layer FL contacts the polarizing plate POL or at a portion where the filling layer FL contacts the panel adhesive layer (e.g., the panel adhesive layer AP of FIG. 3). For example, as the filling layer FL expands or contracts, cracks, delamination, and/or the like may occur in a part of the polarizing plate POL. Accordingly, bubbles may be generated in the cracks, delamination, and/or the like, and the bubbles may be visible to a user of the display device (e.g., the display device DD of FIG. 1).

According to one or more embodiments of the present disclosure, even if (e.g., when) the thickness TH of the adhesive layer AD is equal to or less than about 100 micrometers, the transmittance of the adhesive layer AD with respect to ultraviolet rays may be equal to or less than about 90 %. Accordingly, a crosslinking reaction may sufficiently or suitably occur in an entire (e.g., substantially entire) area of the filling layer FL, and the filling layer FL may have a high crosslinking density. As a result, an elastic modulus of the filling layer FL may increase, and a creep property may decrease. For example, the elastic modulus of the filling layer FL may be equal to or more than about 60 kPa and equal to or less than about 80 kPa. In one or more embodiments, the elastic modulus may be an indentation modulus. In one or more embodiments, the creep property of the filling layer FL may be equal to or more than about 80 % and equal to or less than about 90 %. The creep may refer to a phenomenon in which deformation of the filling layer FL continues over time under a constant load (e.g., indentation load). The creep property may be identified by measuring an initial deformation amount after applying a constant load (e.g., indentation load) to the filling layer FL at a specific (e.g., set or predetermined) temperature, and then measuring a final deformation amount while maintaining substantially the same load. For example, the creep property may be calculated at about 60° C using a formula of “(the final deformation amount – the initial deformation amount) / the initial deformation amount”, but embodiments of the present disclosure are not necessarily limited thereto, and the specific temperature (e.g., 60° C) may be suitably set according to one or more embodiments. As the elastic modulus of the filling layer FL increases and the creep property decreases, a degree (or frequency) of expansion or contraction of the filling layer FL in response to external temperature change may decrease. For example, a thermal expansion coefficient and a thermal contraction coefficient of the filling layer FL may decrease. Accordingly, cracks, delamination, and/or the like that occur in a portion of the polarizing plate POL and/or the like may be prevented (or a degree to or occurrence of which cracks, delamination, and/or the like occur in a portion of the polarizing plate POL and/or the like may be reduced). Therefore, bubbles that are generated in the cracks, delamination, and/or the like may be prevented (or a degree to or occurrence of which bubbles are generated in the cracks, delamination, and/or the like may be reduced).

Variables that determine the transmittance of the adhesive layer AD with respect to ultraviolet rays may include a refractive index of the adhesive layer AD, a chemical composition of the adhesive layer AD, a surface roughness of the adhesive layer AD, and/or the like. In order to set the transmittance of the adhesive layer AD with respect to ultraviolet rays to be equal to or more than about 85 % and equal to or less than about 90 %, the refractive index, the chemical composition, and the surface roughness of the adhesive layer AD may be appropriately or suitably adjusted. For example, the refractive index of the adhesive layer AD may be set to be equal to or more than about 1.49 and equal to or less than about 1.5, but this is merely an example, and the refractive index of the adhesive layer AD may be suitably changed according to one or more embodiments.

The display device (e.g., the display device DD of FIG. 1) according to one or more embodiments may be applied to one or more suitable electronic devices. An electronic device according to one or more embodiments may include the display device as described in one or more embodiments and may further include a module and/or a device having other additional functions in addition to the display device.

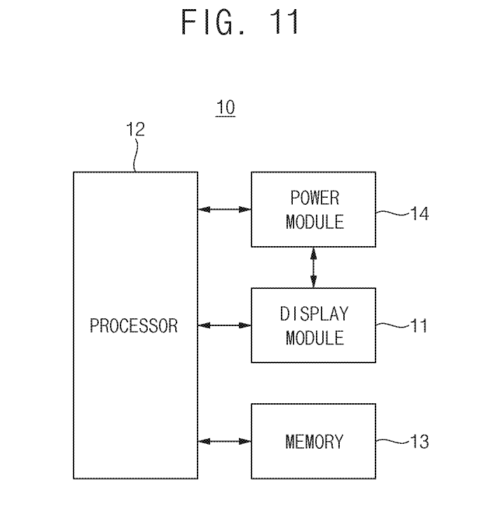

FIG. 11 is a block diagram illustrating an electronic device according to one or more embodiments.

Referring to FIG. 11, an electronic device 10 according to one or more embodiments may include a display module 11, a processor 12, a memory 13, and a power module 14.

The processor 12 may include at least one selected from among a central processing unit (CPU), an application processor (AP), a graphic processing unit (GPU), a communication processor (CP), an image signal processor (ISP), and a controller.

Data information necessary or desired for operation of the processor 12 or the display module 11 may be stored in the memory 15. If (e.g., when) the processor 12 executes an application stored in the memory 15, an image data signal and/or an input control signal may be transmitted to the display module 11, and the display module 11 may process received signal and output image information through a display screen.

The power module 14 may include a power supply module, such as a power adapter or a battery device, and a power conversion module that converts power supplied by the power supply module to generate power required or desired for operation of the electronic device 10.

At least one selected from among the components of the electronic device 10 as described in one or more embodiments may be included in the display device according to one or more embodiments. In one or more embodiments, one or more of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

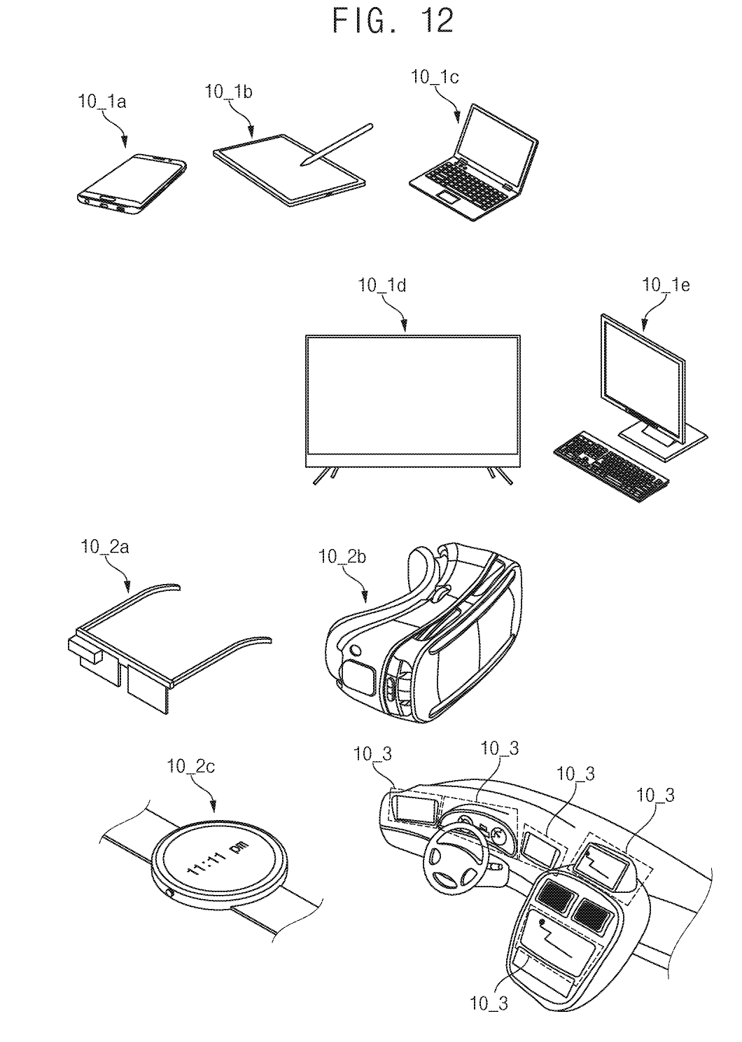

FIG. 12 is a schematic diagram of electronic devices according to one or more embodiments.

Referring to FIG. 12, one or more suitable electronic devices to which display devices according to one or more embodiments are applied may include not only electronic devices for image display, such as a smartphone 10_1a, a tablet PC 10_1b, a laptop 10_1c, a TV 10_1d, a desk monitor 10_1e, and/or the like, but also wearable electronic devices including display modules, such as a smart glass 10_2a, a head mounted display 10_2b, a smart watch 10_2c, and/or the like, vehicle electronic device 10_3 including display modules, such as a vehicle's instrument panel, a center fascia, a center information display (CID) located or provided on a dashboard, a room mirror display, and/or the like.

One or more embodiments of the present disclosure may be applied to one or more suitable display devices. For example, one or more embodiments of the present disclosure may be applicable to one or more suitable display devices, such as display devices for vehicles, ships, and aircraft, portable communication devices, display devices for exhibition or information transmission, medical display devices, and/or the like.

The foregoing is illustrative of one or more embodiments of the present disclosure and is not to be construed as limiting thereof. Although certain embodiments of the present disclosure have been described, those skilled in the art will readily appreciate that one or more suitable modifications may be feasible in one or more embodiments without materially departing from the novel teachings and aspects of the present disclosure. Accordingly, all such modifications are intended to be included within the scope of the present disclosure as claimed in the appended claims. Therefore, it is to be understood that the foregoing is illustrative of one or more suitable embodiments and is not to be construed as limited to the specific embodiments disclosed and that modifications to the disclosed embodiments, as well as one or more embodiments, are intended to be included within the scope of the appended claims and equivalents thereof.

What is claimed is:

1. A display device comprising:
a substrate comprising a hole area, a display area, and a non-display area around at least a portion of the display area;
a circuit layer provided on the substrate and comprising a circuit element;
an element layer provided on the circuit layer and comprising a light-emitting element;
a polarizing plate provided on the element layer and comprising an opening in the hole area;
a filling layer filling the opening of the polarizing plate;
an adhesive layer on the polarizing plate and the filling layer, wherein the adhesive layer has a thickness of equal to or less than 100 micrometers and a transmittance of equal to or less than 90% with respect to ultraviolet rays; and
a cover window on the adhesive layer.

2. The display device as claimed in claim 1, wherein the transmittance of the adhesive layer with respect to ultraviolet rays is equal to or more than 85 %.

3. The display device as claimed in claim 1, wherein a creep property of the filling layer is equal to or more than 80% and equal to or less than 90 %.

4. The display device as claimed in claim 1, wherein an indentation modulus of the filling layer is equal to or more than 60 kPa and equal to or less than 80 kPa.

5. The display device as claimed in claim 1, further comprising:
a component in the hole area.

6. The display device as claimed in claim 1, wherein the element layer defines a hole overlapping the opening in plan view.

7. The display device as claimed in claim 6, further comprising:
a filling member filling the hole.

8. The display device as claimed in claim 1, wherein the filling layer is cured by ultraviolet rays transmitted through the adhesive layer.

9. The display device as claimed in claim 8, wherein the filling layer and the adhesive layer are cured concurrently.

10. The display device as claimed in claim 1, wherein a refractive index of the adhesive layer is equal to or more than 1.49 and equal to or less than 1.5.

11. A method of manufacturing a display device, the method comprising:
forming a preliminary polarizing plate on a display panel;
forming a polarizing plate by forming an opening in the preliminary polarizing plate;
forming a filling layer filling the opening;
forming an adhesive layer on the polarizing plate and the filling layer, wherein the adhesive layer has a thickness of equal to or less than 100 micrometers and a transmittance of equal to or less than 90% with respect to ultraviolet rays; and
forming a cover window on the adhesive layer.

12. The method as claimed in claim 11, further comprising:
partially curing the filling layer after the forming of the filling layer and before the forming of the adhesive layer.

13. The method as claimed in claim 12, further comprising:
fully curing the filling layer after the forming of the cover window.

14. The method as claimed in claim 13, wherein the adhesive layer is cured by the fully curing of the filling layer.

15. The method as claimed in claim 11, wherein the transmittance of the adhesive layer with respect to ultraviolet rays is equal to or more than 85%.

16. The method as claimed in claim 11, wherein a creep property of the filling layer is equal to or more than 80 % and equal to or less than 90 %, and
an indentation modulus of the filling layer is equal to or more than 60 kPa and equal to or less than 80 kPa.

17. An electronic device comprising:
a display device comprising:
a substrate comprising a hole area, a display area, and a non-display area around at least a portion of the display area;
a circuit layer provided on the substrate and comprising a circuit element;
an element layer provided on the circuit layer and comprising a light-emitting element;
a polarizing plate provided on the element layer and comprising an opening in the hole area;
a filling layer filling the opening of the polarizing plate;
an adhesive layer on the polarizing plate and the filling layer, wherein the adhesive layer has a thickness of equal to or less than 100 micrometers and a transmittance of equal to or less than 90% with respect to ultraviolet rays; and
a cover window on the adhesive layer; and
a memory provided to store data information.

18. The electronic device as claimed in claim 17, wherein the transmittance of the adhesive layer with respect to ultraviolet rays is equal to or more than 85 %.

19. The electronic device as claimed in claim 17, wherein a creep property of the filling layer is equal to or more than 80 % and equal to or less than 90 %, and an indentation modulus of the filling layer is equal to or more than 60 kPa and equal to or less than 80 kPa.

20. The electronic device as claimed in claim 17, wherein a refractive index of the adhesive layer is equal to or more than 1.49 and equal to or less than 1.5.
